(19) United States
(12) Patent Application Publication
(10) Pub. No.: US 2003/0109111 A1
(43) Pub. Date: Jun. 12, 2003

(54) Method for forming an ONO structure in one chamber

(75) Inventors: Jung-Yu Hsieh, Hsin-Chu (TW); Chin-Hsiang Lin, Nan-Tao (TW)

Correspondence Address: LOWE HAUPTMAN GILMAN & BERNER, LLP, Suite 310, 1700 Diagonal Road, Alexandria, VA, 22314, US

(73) Assignee: MACRONIX INTERNATIONAL CO., LTD.

(21) Appl. No.: 10/002,978

(22) Filed: Dec. 6, 2001

(51) Int. Cl. H01L 21/76

(52) U.S. Cl. 438/400

(57) ABSTRACT

A method for forming an ONO structure in one chamber. The method at least includes the following steps. First of all, a substrate is provided. Then, a first oxide layer is formed on the substrate. Next, a first buffer layer is formed on the first oxide layer, and a silicon nitride layer is formed on the first buffer layer. Next, a second buffer layer is formed on the silicon nitride layer. Finally, a second oxide layer is formed on the second buffer layer.

### BACKGROUND OF THE INVENTION

1. Field of the Invention

The present invention generally relates to a method for forming an oxide-nitride-oxide structure of a memory cell, and more particularly to a method for forming an oxide-nitride-oxide structure in one chamber.

2. Description of the Prior Art

Flash memory is the most potential memory in the semiconductor industry. Flash memory has been broadly applied to repeatedly access data and to remain assessable during power break down, such as the film of digital camera or the basic input-output system of a motherboard. Because flash memory has the advantages of electrically erasable and programmable mechanisms, it can simultaneously proceed the erase and the program mechanisms to all flash memory cells in the whole memory array. Accordingly, how to advance the performance and reduce the cost of the flash memory became an important subject.

The conventional flash memory structure is shown in FIG. 1A. First a substrate 100 is provided, and a field oxide layer 101 is formed on the substrate 100 by local oxidation (LOCOS) to define an active area. A tunnel oxide layer 102 is formed on the substrate 100. A floating gate 104 is formed on the tunnel oxide layer 102. The tunnel oxide layer 102 and the ONO structure are dielectric layers. The floating gate 104 is poly for storing and erasing date. A control gate 108 is formed over the floating gate 104. A dielectric layer 106 with an ONO structure comprising a sandwiched type of oxide-nitride-oxide layer 106 is formed between the control gate 108 and the floating gate 104. The ONO multi-layered dielectric containing three layers; namely a first oxide layer 106a, a nitride layer 106b, and a second oxide layer 106c. An N-type source/drain 110/112 region is formed in the substrate 100 beside the floating gate 104. Oxide spacer 114 are formed on the side-wall of the floating gate 104 and the control gate 108 to protect the transistor from being damaged.

The function of a flash memory operates when a positive voltages are applied to drain 112 and control gate 108 that force electrons to inject from the substrate near drain 112 to floating gate 104. To erase the memory device, a negative voltage is applied to the control gate 108 and positive voltage is applied to source 110 that force electrons through tunnel to source region.

The traditional ONO structure of a flash memory is shown in FIG. 1B, first silane (SiH₄) and nitrogen oxides (N₂O) is introduced to deposit the bottom oxide layer 106A of the ONO structure, when the reaction is completed. In the next step, silane (SiH₄) and ammonia (NH₃) are introduced to deposit the nitride layer 106B. In the third step, silane (SiH₄) and nitrogen oxides (N₂O) are introduced again to deposit the upper oxide layer 106C. A complete ONO structure of a flash memory is thus formed.

The traditional fabrication method for producing ONO structure 106 is conducted by LPCVD method under a temperature of about 400 to 500° C. in a batch type furnace process. The batch type processing is proceeded in a boat carrying about 150 pieces of wafers. The disadvantage of the batch typed processing is that if there is any accident occurs, for example, a short circuit occurrence would cause a large cost of loss.

In the traditional ONO layer fabrication, it is also noted that when the layers of oxide and nitride are constructed, it would be necessary that the process must be conducted by separate chamber. A separate chamber for proceeding the construction of an ONO structure is a time consuming task especially when the process is proceeded under a thermal treatment, the annealing process associated with the thermal treatment requires a long time to reorganize the structure of the ONO structure.

Another defect associated with the structure of ONO is due to the existence of rough interfaces among oxide-nitride-oxide layers, especially when there is a higher nitride film roughness on this ONO structure. This roughness contrast can be an obstacle for the promotion of flash memory speed efficiency.

In view of the prior art described, it is a desire to provide a method for forming an oxide-nitride-oxide structure in one chamber to improve nitride layer roughness problem in the ONO structure.

### SUMMARY OF THE INVENTION

In accordance with the present invention, a method for forming an oxide-nitride-oxide structure in one chamber that substantially can use one chamber to form ONO structure in conventional process.

One object of the present invention is to provide a method for forming an oxide-nitride-oxide structure in one chamber to increase flash memory speed efficiency.

Another object of the present invention is to provide a method for forming an oxide-nitride-oxide structure in one chamber to improve nitride layer roughness problem in the ONO structure.

In order to achieve the above object, the present invention provides a method for forming an oxide-nitride-oxide structure in one chamber. The method at least includes the following steps. First of all, a substrate is provided. Then, a first oxide layer is formed on the substrate. Next, a first buffer layer is formed on the first oxide layer, and a silicon nitride layer is formed on the first buffer layer. Next, a second buffer layer is formed on the silicon nitride layer. Finally, a second oxide layer is formed on the second buffer layer.

### BRIEF DESCRIPTION OF THE DRAWINGS

The foregoing aspects and many of the attendant advantages of this invention will become more readily appreciated as the same becomes better understood by referring to the following detailed description, when taken in conjunction with the accompanying drawings, wherein:

FIG. 1A is a diagram showing the flash memory having an ONO structure in prior art techniques;

FIG. 1B is a diagram of the ONO structure in prior art techniques;

FIG. 2A is cross-sectional views of a method for forming an oxide-nitride-oxide structure in one chamber in accordance with one preferred embodiment of the present invention;

FIG. 2B is a diagram of the ONO structure in this invention technique.

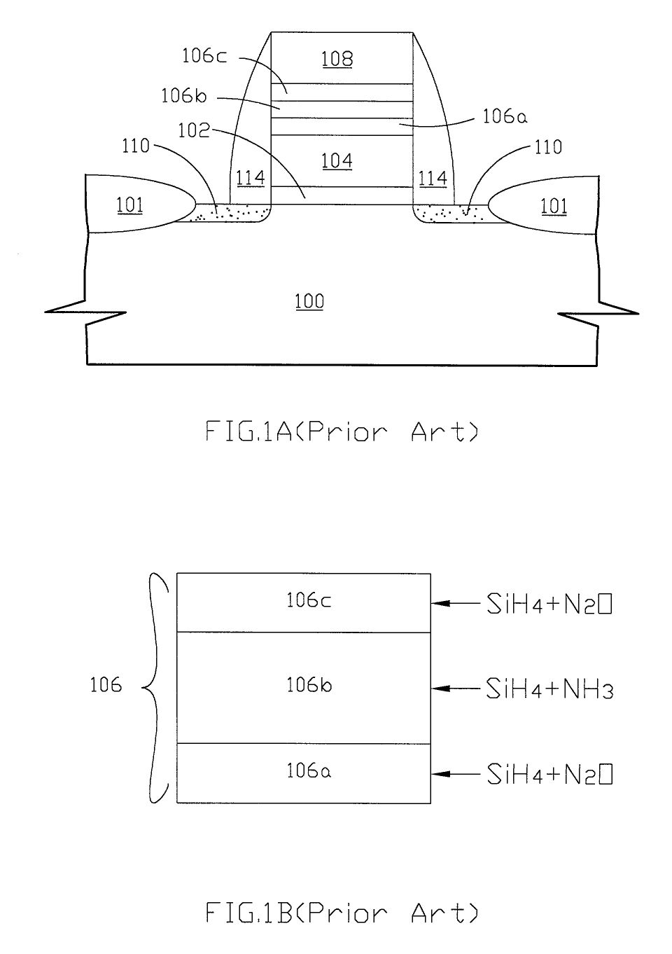

### DESCRIPTION OF THE PREFERRED EMBODIMENT

Some sample embodiments of the invention will now be described in greater detail. Nevertheless, it should be recognized that the present invention can be practiced in a wide range of other embodiments besides those explicitly described, and the scope of the present invention is expressly not limited except as specified in the accompanying claims.

Moreover, while the present invention is illustrated by a number of preferred embodiments directed to silicon semiconductor devices, it is not intended that these illustrations be a limitation on the scope or applicability of the present invention. Thus, it is not intended that the semiconductor devices of the present invention be limited to the structures illustrated. These devices are included to demonstrate the utility and application of the present invention to presently preferred embodiments.

Further, various parts of the semiconductor elements have not been drawn to scale. Certain dimensions have been exaggerated in relation to other dimensions in order to provide a clear illustration and understanding of the present invention. For example, although the embodiments illustrated herein are shown in two dimensional views with various regions having width and depth, it should be clearly understood that these regions are illustrations of only a portion of a single cell of a device, which may include a plurality of such cells arranged in a three-dimensional structure. Accordingly, these regions will have three dimensions, including length, width and depth, when fabricated in an actual device.

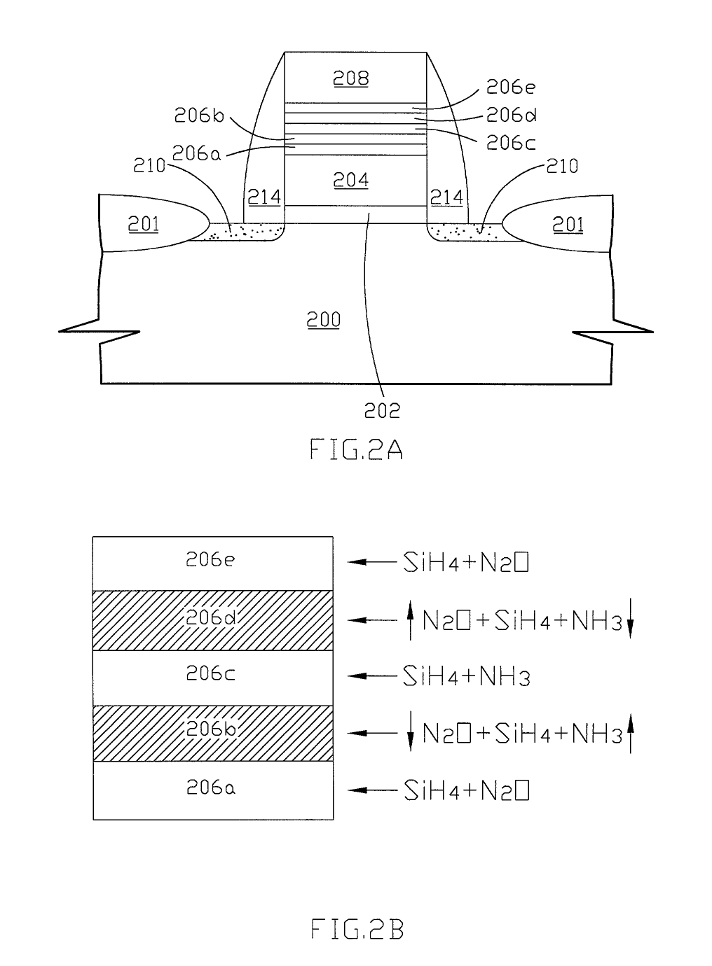

FIG.2A is cross-sectional views of a method for forming an oxide-nitride-oxide structure in one chamber in accordance with one preferred embodiment of the present invention;

FIG. 2B is a diagram of the ONO structure in this invention technique.

The invention flash memory structure is shown in FIG.2A. Firstly, a semiconductor substrate 200 is provided, and a field oxide layer 201 is formed on the substrate 200 by local oxidation (LOCOS) to define an active area. The semiconductor substrate 200 comprises silicon. A tunnel oxide layer 202 is formed on the semiconductor substrate 200. A floating gate 204 is formed on the tunnel oxide layer 202. The tunnel oxide layer 202 and the ONO structure are dielectric layers. The floating gate 204 is poly for storing and erasing data. A control gate 208 is formed over the floating gate 204. A dielectric layer 206 with an O—SiON—N—SiON—O structure comprising a sandwiched type of oxide-nitride-oxide layer 206 is formed between the control gate 208 and the floating gate 204. The O—SiON—N—SiON—O multi-layered dielectric containing five layers; namely a first oxide layer 206a, a first buffer layer 206b, a nitride layer 206c, a second buffer layer 206d, and a second oxide layer 206e. An N-type source/drain 210/212 region is formed in the substrate 200 beside the floating gate 204. Oxide spacer 214 are formed on the side-wall of the floating gate 204 and the control gate 208 to protect the transistor from being damaged.

The function of a flash memory operates when a positive voltages are applied to drain 212 and control gate 208 that force electrons to inject from the substrate near drain 212 to floating gate 204. To erase the memory device, a negative voltage is applied to the control gate 208 and positive voltage is applied to source 210 that force electrons to tunnel source region.

The invention O—SiON—N—SiON—O structure 206 of a flash memory is shown in FIG. 2B. The O—SiON—N—SiON—O structure 206 includes a first oxide layer 206a overlying the floating gate 204. A first buffer layer 206b overlies first oxide layer 206a. A nitride layer 206c overlies first buffer layer 206b. A second buffer layer 206d overlies nitride layer 206c. A second oxide layer 206e overlies second buffer layer 206d. The O—SiON—N—SiON—O structure 206 is deposited in one wafer and in one chamber. The O—SiON—N—SiON—O structure 206 also can apply another device that have ONO structure such as NROM.

The first oxide layer 206a is formed to a thickness between about 30 and 100 angstroms on the floating gate 204 by introducing silane gas (SiH₄) at between about 5 and 200 seconds and nitrogen oxide gas (N₂O) at between about 5 and 200 seconds. The first oxide layer 206a deposition rate is between about 0.1 and 20 Å/sec. A flow of silane gas is between about 0.1 and 100 sccm. A flow of nitrogen oxide gas is between about 10_and 1000 sccm. The first oxide layer 206a is formed by using a low pressure vapor chemical deposition method(LPCVD). The LPCVD process is carried out at a temperature of between about 500° C. and 2000° C. In the embodiment, temperature of this layer is preferable 800° C.

The first buffer layer 206b is formed to a thickness of between about 0.5 and 5 angstroms on the first oxide layer 206a by using a low pressure vapor chemical deposition (LPCVD) method and introducing silane gas (SiH₄) at between about 0.5 and 20 seconds, nitrogen oxide gas (N₂O) at between about 0.5 and 20 seconds, and ammonia (NH₃) gas at between about 0.5 and 20 seconds. The LPCVD process is carried out at a temperature of between about 500° C. and 2000° C. In the embodiment, temperature of this layer is preferable 800° C. The first buffer layer 206b deposition rate is between about 0.1 and 5 Å/sec. A flow of silane gas is between about 0.1 and 1000 sccm. A flow of nitrogen oxide gas is between about 0.1 and 1000 sccm. A flow of ammonia gas is between about 0.1 and 1000 sccm. The first buffer layer 206b is silicon oxynitride (SiON) layer. The first buffer layer 206b is deposited by gradually reducing the supply of nitrogen oxide gas, in the mean while, gradually increasing the supply of ammonia gas. In this step, silane gas is also provided for the deposition continually.

The nitride layer 206c is formed to a thickness of between about 30 and 200 angstroms on first buffer layer 206b by using a low pressure vapor chemical deposition method (LPCVD) and introducing silane gas (SiH₄) at between about 10 and 300 seconds and ammonia (NH₃) gas at between about 10 and 300 seconds. The LPCVD process is carried out at a temperature of between about 500 ° C. and 2000° C. In the embodiment, temperature of this layer is preferable 800° C. The nitride layer 206c deposition rate is between about 0.5 and 100 Å/sec. A flow of silane gas is between about 0.1 and 100 sccm. A flow of ammonia gas is between about 10 and 1000 sccm. The nitride layer 206c is deposited by stop providing the nitrogen oxide gas and start providing the ammonia gas for deposition. In this step, silane gas is also provided for the deposition continually.

The second buffer layer 206d is formed to a thickness of between about 0.5 and 5 angstroms on the nitride layer 206c by using a low pressure vapor chemical deposition method and introducing silane gas (SiH₄) at between about 0.5 and 20 seconds, nitrogen oxide gas (N₂O) at between about 0.5 and 20 seconds, and ammonia (NH₃) gas at between about 0.5 and 20 seconds. The LPCVD process is carried out at a temperature of between about 500 ° C. and 2000° C. In the embodiment, temperature of this layer is preferable 800° C. The second buffer layer 206d deposition rate is between about 0.1 and 5 Å/sec. A flow of silane gas is between about 0.1 and 100 sccm. A flow of nitrogen oxide gas is between about 0.1 and 1000 sccm. A flow of ammonia gas is between about 0.1 and 1000 sccm. The second buffer layer 206d is silicon oxynitride (SiON) layer. The second buffer layer 206d is deposited by gradually reducing the supply of ammonia gas, in the mean while, gradually increasing the supply of nitrogen oxide gas. In this step, silane gas is also provided for the deposition continually.

The second oxide layer 206e is formed to a thickness of between about 30 and 100 angstroms on second buffer layer 206d by using a low pressure vapor chemical deposition method and introducing silane gas (SiH₄) at between about 5 and 200 seconds and nitrogen oxide gas (N₂O) at between about 5 and 200 seconds. The LPCVD process is carried out at a temperature of between about 500° C. and 2000° C. In the embodiment, temperature of this layer is preferable 800° C. The second oxide layer 206e deposition rate is between about 0.1 and 20 Å/sec. A flow of silane gas is between about 0.1 and 100 sccm. A flow of nitrogen oxide gas is between about 10 and 1000 sccm. The second oxide layer 206e is deposited by stop providing ammonia gas and supply only the nitrogen oxide gas for deposition. In this step, silane gas is also provided for the deposition continually.

Thus, an O—SiON—N—SiON—O structure with smooth buffer layer in the intermediate layer is thus constructed. The layer between first oxide layer and nitride layer is the layer of silicon oxynitride (SiON) with a smooth buffer layer that is initially an oxide composition and has a tendency slowly turning to nitride until the composition is totally nitride. In the side of nitride layer, there is a layer of silicon oxynitride (SiON) with a smooth buffer layer that is initially a nitride composition and has a tendency slowly turning to oxide until the composition is totally oxide. This smooth buffer layer can be easily seen from reflective index changes of oxide layer with a value of 1.46 into nitride layer with a value of 2.0. It is obvious that the first buffer layer SiON of the constructed O—SiON—N—SiON—O structure has a reflective index changes varies slowly from 1.46 to 2.0 and also a reflective index of 2.0 slowly changes to 1.46 on the second buffer layer SiON of the constructed O—SiON—N—SiON—O structure.

The SiON lies between oxide to nitride layers and nitride to oxide layer is termed as a smooth buffer layers which is used to reduce the boundary roughness among ONO layers.

It should be emphasized here, the deposited O—SiON—N—SiON—N layer is conducted in one chamber such that the time required in the annealing process associated with the various thermal treatments can be reduced a lot.

The foregoing description of the preferred embodiments in this invention has been presented for purpose of illustration and description. It is not intended to be exhaustive or to limit the invention to the precise form disclosed. Numerous modifications or variations are possible in light of the above teaching. The embodiments were chosen and described to provide the best illustration of the principles of the invention and its practical application to thereby enable one of the ordinary skill in the art to utilize the invention in various embodiments and with various modifications which are suited to the particular use contemplated. All such modifications and variations are within the scope of the invention as determined by appended claims when interpreted in accordance with the breadth to which they are legally and equitably entitled.

The method for forming an oxide-nitride-oxide structure in one chamber using the above explained method, has the following advantages:

1. The present invention is to provide a method for forming an oxide-nitride-oxide structure in one chamber to increase flash memory speed efficiency.

2. The present invention is to provide a method for forming an oxide-nitride-oxide structure in one chamber to improve nitride layer roughness problem in the ONO structure.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for forming an oxide-nitride-oxide structure in one chamber, the method comprising the steps of:
providing a substrate;
forming a first oxide layer on said substrate;
forming a first buffer layer on said first oxide layer;
forming a silicon nitride layer on said first buffer layer;
forming a second buffer layer on said silicon nitride layer; and
forming a second oxide layer on said second buffer layer.

2. The method according to claim 1, wherein said first oxide layer is formed by introducing silane gas and nitrogen oxide gas.

3. The method according to claim 1, wherein said first buffer layer is silicon oxynitride (SiON) layer.

4. The method according to claim 3, wherein said first buffer layer is formed by introducing silane (SiH₄), nitrogen oxide (N₂O) and ammonia (NH₃) gas.

5. The method according to claim 1, wherein said silicon nitride layer is formed by introducing silane (SiH₄) and ammonia (NH₃) gas.

6. The method according to claim 1, wherein said second buffer layer is silicon oxynitride (SiON) layer.

7. The method according to claim 6, wherein said second buffer layer is formed by introducing silane (SiH₄), nitrogen oxide (N₂O) and ammonia (NH₃) gas.

8. The method according to claim 1, wherein said second oxide layer is formed by introducing silane (SiH₄) gas and nitrogen oxide (N₂O) gas.

9. The method according to claim 1, wherein said oxide-nitride-oxide structure is formed in one wafer.

10. A method for forming an oxide-nitride-oxide structure, the method comprising the steps of:
providing a substrate;
forming a first oxide layer on said substrate;
forming a first buffer layer on said first oxide layer;
forming a silicon nitride layer on said first buffer layer;
forming a second buffer layer on said silicon nitride layer;
and
forming a second oxide layer on said second buffer layer, wherein said above-mentioned layer is formed in one chamber and in one wafer.

11. The method according to claim 10, wherein said ONO structure is formed by low pressure chemical vapor deposition (LPCVD) method.

12. The method according to claim 10, wherein said first oxide layer is formed by introducing silane gas and nitrogen oxide gas.

13. The method according to claim 10, wherein said first buffer layer is silicon oxynitride (SiON) layer.

14. The method according to claim 13, wherein said first buffer layer is formed by introducing silane, nitrogen oxide and ammonia gas.

15. The method according to claim 10, wherein said silicon nitride layer is formed by introducing silane and ammonia gas.

16. The method according to claim 10, wherein said second buffer layer is silicon oxynitride (SiON) layer.

17. The method according to claim 16, wherein said second buffer layer is formed by introducing silane, nitrogen oxide and ammonia gas.

18. The method according to claim 10, wherein said second oxide layer is formed by introducing silane gas and nitrogen oxide gas.

19. A method for forming an oxide-nitride-oxide structure, the method comprising the steps of:
providing a substrate;
forming a first oxide layer on said substrate, wherein said first oxide layer is formed by introducing silane gas and nitrogen oxide gas;
forming a first silicon oxynitride layer on said first oxide layer, wherein said first buffer layer is formed by introducing by introducing silane, nitrogen oxide and ammonia gas;
forming a silicon nitride layer on said first buffer layer, wherein said silicon nitride layer is formed by introducing silane and ammonia gas;
forming a second silicon oxynitride layer on said silicon nitride layer, wherein said second buffer layer is formed by introducing silane, nitrogen oxide and ammonia gas; and forming a second oxide layer on said second buffer layer, wherein said second oxide layer is formed by introducing silane gas and nitrogen oxide gas, and wherein said above-mentioned layer is formed in one chamber and in one wafer.
